(19) United States
(12) Patent Application Publication
(10) Pub. No.: US 2007/0065968 A1
(43) Pub. Date: Mar. 22, 2007

(54) Fabrication of silicon microphone

(76) Inventors: Kit-Wai Kok, Singapore (SG); Kok Meng Ong, Singapore (SG); Kathirgamasundaram Sooriakumar, Singapore (SG); Bryan Keith Patmon, Singapore (SG)

Correspondence Address: Jay S Cinamon;Abelman Frayne & Schwab, 666 Third Avenue 10th Floor, New York, NY, 10017, US

(21) Appl. No.: 10/558,885

(22) PCT Filed: May 26, 2004
(86) PCT No.: PCT/SG04/00152

§ 371 Date: Oct. 3, 2006

(30) Foreign Application Priority Data
May 26, 2003 (SG) 200302854-5

(51) Int. Cl. H01L 21/00; H01L 29/84

(52) U.S. Cl. 438/53; 438/50; 257/416

(57) ABSTRACT

A silicon microphone is formed using the steps of providing a first wafer including a layer of heavily doped silicon, a layer of silicon and an intermediate layer of oxide between the two silicon layers. The first wafer has a first major surface on one surface of the layer of heavily doped silicon and a second major surface on the layer of silicon. A second wafer of silicon has a first major surface and a second major surface. A layer of oxide is formed on at least the first major surfaces of the first and second wafers. A cavity is etched through the oxide layer on the first major surface of the first wafer and into the layer of heavily doped silicon. The first major surface of the first wafer is bonded to the first major surface of the second wafer. A metal layer is formed on the second major surface of the second wafer. Acoustic holes are patterned and etched in the metal layer and in the second major surface of the second wafer. At least one electrode is formed on the heavily doped silicon of the first wafer and at least one electrode is formed on the second wafer. The oxide layer of the first wafer is etched from at least the back of a diaphragm during manufacturing of the silicon microphone.

### FIELD OF INVENTION

The invention relates to silicon microphones and in particular to the fabrication of silicon microphones.

### BACKGROUND

A capacitive microphone typically includes a diaphragm including an electrode attached to a flexible member and a backplate parallel to the flexible member attached to another electrode. The backplate is relatively rigid and typically includes a plurality of holes to allow air to move between the backplate and the flexible member. The backplate and flexible member form the parallel plates of a capacitor. Acoustic pressure on the diaphragm causes it to deflect which changes the capacitance of the capacitor. The change in capacitance is processed by electronic circuitry to provide an electrical signal that corresponds to the change.

Microelectronic mechanical devices (MEMS), including miniature microphones, are fabricated with techniques commonly used for making integrated circuits. Potential uses for MEMS microphones include microphones for hearing aids and mobile telephones, and pressure sensors for vehicles.

Many available MEMS microphones involve a complex fabrication process that includes numerous masking and etching steps. As the complexity of the fabrication process increases there is a greater risk of the devices failing the testing process and being unusable.

### SUMMARY OF INVENTION

It is the object of the present invention to provide a fabrication process for silicon microphones that has a low number of process steps or to at least provide the public with a useful choice.

In broad terms the invention comprises a method of manufacturing a silicon microphone including the steps of:
providing a first wafer including a layer of heavily doped silicon, a layer of silicon and an intermediate layer of oxide between the two silicon layers and having a first major surface on one surface of the layer of heavily doped silicon and a second major surface on the layer of silicon,
providing a second wafer of silicon having a first major surface and a second major surface,
forming a layer of oxide on at least the first major surface of the first wafer,
forming a layer of oxide on at least the first major surface of the second wafer,
etching a cavity through the oxide layer on the first major surface of the first wafer and into the layer of heavily doped silicon,
bonding the first major surface of the first wafer to the first major surface of the second wafer,
forming a metal layer on the second major surface of the second wafer,
patterning and etching acoustic holes in the metal and in the second major surface of the second wafer, and
forming at least one electrode on the heavily doped silicon of the first wafer and at least one electrode on the second wafer and
further including the step of etching the oxide layer of the first wafer from at least the back of a diaphragm during manufacturing of the silicon microphone.

The first wafer may be thinned to form a diaphragm either before or after bonding to the second wafer. Alternatively the first wafer may include a diaphragm before processing.

Preferably the step of forming an oxide layer on at least one major surface of both wafers includes forming an oxide layer on both major surfaces of both wafers.

Preferably the oxide layers formed on the major faces of the wafers are grown on the major surfaces of the wafers. Alternatively any other suitable method may be used to form the oxide layers.

If an oxide layer is formed on the second major surface of the second wafer, preferably this layer is removed before the first wafer is thinned.

If an oxide layer is formed on the second major surface of the first wafer, preferably this layer is removed before the first wafer is thinned.

The step of forming a layer of metal on the other major surface of the second wafer may be by sputtering metal onto the second major surface of the second wafer.

In one embodiment the invention further comprises etching a portion of the second major wafer from its second major surface to close to its first major surface, the portion being about the perimeter of the wafer. Preferably this etching is performed when the acoustic holes are etched.

Preferably when the first wafer is thinned at its second major surface, the first wafer is thinned to the intermediate oxide layer.

In one embodiment the step of forming electrodes on the heavily doped silicon layer of the first wafer and on the second wafer is performed by forming a metal electrode layer over the entire exposed surface of the heavily doped silicon layer of the first wafer and the exposed surface of the first major surface of the second wafer. This layer of metal is then etched to form the electrodes.

In an alternative embodiment the step of forming electrodes on the heavily doped silicon layer of the first wafer and on the second wafer may be performed by sputtering metal and using a shadow mask to pattern the electrodes.

In one embodiment the layer of metal formed on the second major surface of the second wafer is an alloy or mixture of chromium and gold. Alternatively any other suitable conductive metal may be used for the electrode.

When the acoustic holes are patterned and etched info the metal layer formed on the second major surface of the second wafer, anchors are generally patterned and formed at the edges of the wafer in the metal layer formed on the second major surface of the second wafer. One of these anchors may be used as an electrode. The other anchors may include both a portion of the second wafer and a cover portion of metal. The cover metal portions are ideally separated from the metal surrounding the acoustic holes. The separation step may be performed by patterning and etching the separation when the acoustic holes are patterned and etched in the metal.

In broad terms in another aspect the invention comprises a silicon microphone formed using the method of the invention.

### BRIEF DESCRIPTION OF DRAWINGS

The method of fabricating a silicon microphone will be further described by way of example only and without intending to be limiting with reference to the following drawings, wherein:

FIG. 1A is a side view of the first wafer before fabrication;

FIG. 1B is a side view of the second wafer before fabrication;

FIG. 2A is a side view of the first wafer after the deposition or growth of oxide;

FIG. 2B is a side view of the second wafer after the deposition or growth of oxide;

FIG. 3 is a side view of the first wafer after a cavity has been patterned and etched;

FIG. 4 is a side view of the two wafers bonded together;

FIG. 5 is a side view of the two wafers after the oxide layers have been stripped;

FIG. 6 is a side view of the two wafers after thinning the first wafer;

FIG. 7 is a side view of the two wafers after forming metal on the second wafer and forming acoustic holes in the second wafer;

FIG. 7A is a second side view of the two wafers after forming metal on the second wafer and forming acoustic holes in the second wafer taken about line A-A on FIG. 11;

FIG. 8 is a side view of the two wafers after etching oxide from the bond between the two wafers;

FIG. 8A is a second side view of the two wafers after etching oxide from the bond between the two wafers taken about line A-A of FIG. 11;

FIG. 9 is a side view of the two wafers after forming metal over the heavily doped layer of the first wafer;

FIG. 9A is a second side view of the two wafers after forming metal over the heavily doped layer of the first wafer taken about line A-A of FIG. 11;

FIG. 10 is a side view of the two wafers after electrodes have been formed;

FIG. 10 A is a second side view of the two wafers after electrodes have been formed taken about line A-A of FIG. 11;

FIG. 11 is a top view of the completed silicon microphone;

FIG. 12 is a side view of a second embodiment of silicon microphone without electrodes;

FIG. 13 is a side view of the microphone of FIG. 12 with electrodes; and

FIG. 14 is a side view of a silicon microphone with corrugations in the diaphragm.

### DETAILED DESCRIPTION

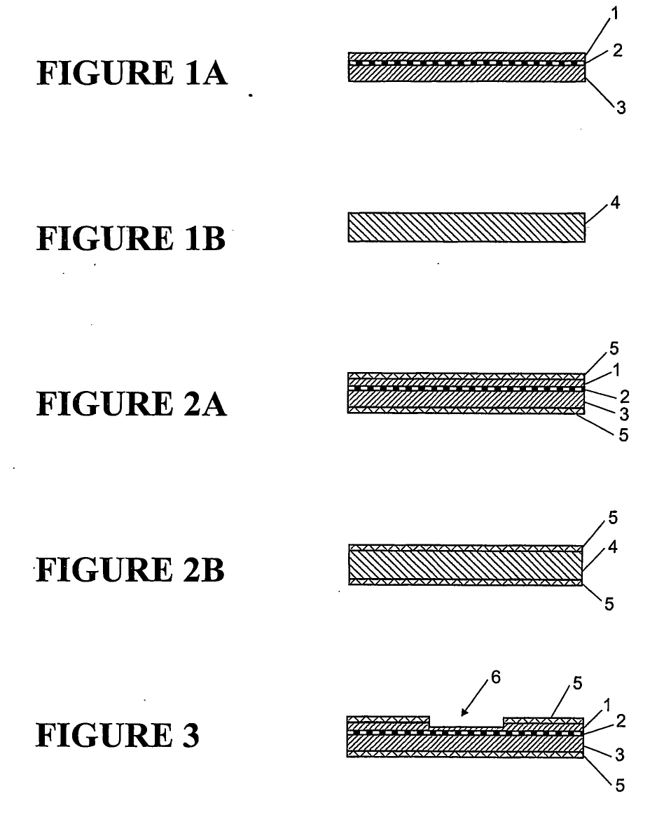

FIG. 1A is a side view of the first wafer used for fabricating a silicon microphone. This wafer is formed from a first layer 1 of highly doped silicon, a middle layer 2 of oxide and the third layer 3 of silicon substrate. In one embodiment the first layer is p⁺⁺ doped silicon and the third layer is an n-type substrate. In an alternative embodiment the first layer may be n⁺⁺ doped silicon and the third layer may be a p-type substrate. Typically the first layer 1 is of the order of 4 microns thick and the second layer is of the order of 2 microns thick. The thickness of these layers used in the silicon microphone will depend on the required characteristics of the microphone. The substrate layer is thicker than the other two layers and for example may be of the order of about 400 to 600 microns thick.

In alternative embodiments the substrate may be thinner than described above. Alternatively the substrate may be patterned to form a diaphragm either before processing or before or after bonding to the second wafer.

It should be noted that the side views shown are not drawn to scale and are given for illustrative purposes only.

FIG. 1B is a side view of the second wafer used for fabricating a silicon microphone. This wafer comprises a silicon wafer 4. The wafer is heavily doped silicon and may be either p-type or n-type silicon. In a preferred embodiment the wafer is <100> silicon. In other embodiments different silicon surfaces or structures may be used.

Although FIGS. 1A and 1B are side views of the two wafers, the wafers are three dimensional with two major surfaces. The two major surfaces of the first wafer are the top and bottom surfaces (not shown in FIG. 1A). The first major surface, the top surface, comprises highly doped silicon. The second major surface, the bottom surface, comprises the silicon substrate.

In FIG. 1B the major surfaces are at the top and bottom of the wafer and both comprise the heavily doped silicon wafer.

In fabricating the silicon microphone the two wafers are initially processed separately before being bonded together and further processed.

FIGS. 2A and 2B show the first and second wafers after oxide 5 has been formed on the major surfaces of the wafers. Oxide is typically formed on both surfaces of both wafers through thermal growth or a deposition process. Forming oxide on both major surfaces of each wafer reduces the risks of distorting the wafer that would occur if oxide was formed on only one side of each wafer. In an alternative embodiment oxide is formed on only one major surface of each wafer. As can be seen in FIGS. 2A and 2B the thickness of the oxide layers 5 is less than the thickness of the silicon wafer.

It is to be understood that any other suitable dielectric or insulative material, for example silicon nitride, may be used in place of the oxide layer.

FIG. 3 shows one embodiment in which a cavity 6 is patterned and etched into the first major surface of the first wafer. In this step a portion of the heavily doped silicon layer is etched away to produce a thin section of the heavily doped portion 1. A wet or dry silicon etch may be used. The thickness of the thin section determines properties of the silicon microphone as this section will eventually form the diaphragm of the microphone. In one embodiment a reactive ion etch (RIE) is used to form the cavity. This etch is a time etch so the final thickness of the thin section of the heavily doped portion depends on the etching time.

The desired shape of the cavity is determined from the required properties of the silicon microphone.

In one embodiment a portion of the wafer may be etched from doped portion 1 to oxide layer 2 to allow an electrode to be formed on second wafer 4 at a later processing stage. This can be etched when the diaphragm cavity is etched.

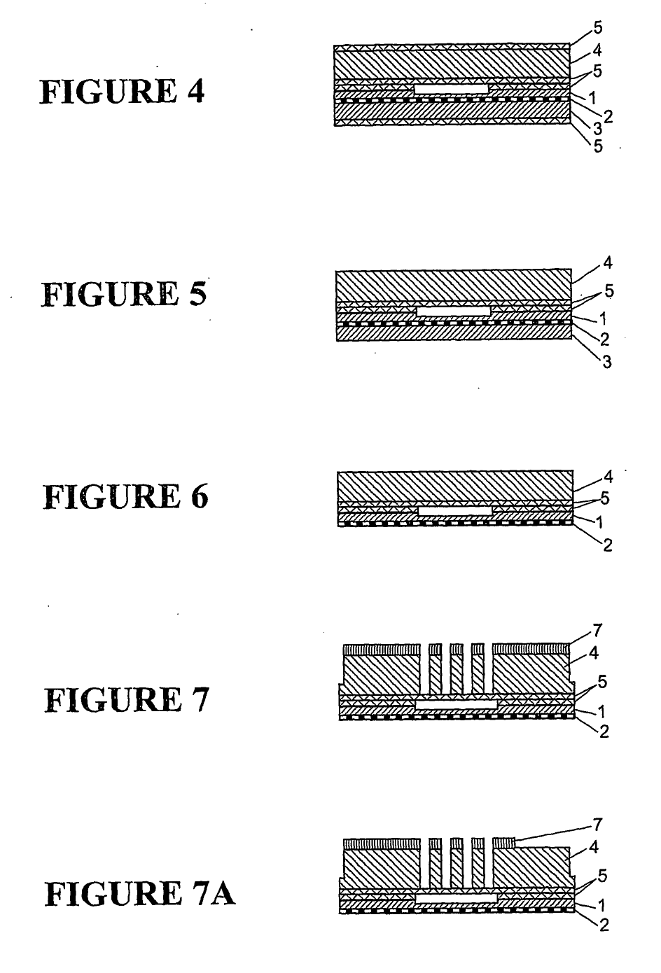

As shown in FIG. 4 the two wafers are bonded together. The major surfaces bonded together are the first major surface 1 of the first wafer and one of the major surfaces of the second wafer 4. In a preferred embodiment the two wafers are bonded together using fusion bonding. As shown in FIG. 4 it is the oxide layer 5 of second wafer 4 and the patterned oxide layer 5 of the first wafer that are bonded together.

FIG. 5 shows the two wafers after the oxide layers are stripped from the exposed major surfaces of these wafers. Oxide stripping is well known and any suitable technique may be used to strip the oxide from the exposed surfaces.

FIG. 6 shows the two wafers after the silicon substrate has been removed from the first wafer. In the preferred embodiment this thinning is performed in a single operation. Any suitable technique may be used to remove the layer of substrate from the first wafer.

After thinning of the first wafer acoustic holes are patterned and etched into the second wafer as shown in FIG. 7. To pattern and etch the acoustic holes the first step is to form a layer of metal 7 on the outer major surface of the second wafer 4. In one embodiment metal is sputtered onto the major surface of the second wafer. The metal is then covered with a layer of resist and the resist is then patterned. Etching is performed to etch the acoustic holes through the metal 7 and silicon 4. The etching may also etch the oxide layer 5 at the bottom of the acoustic holes to provide access between the acoustic holes and the cavity formed in the heavily doped silicon layer 1 of the first wafer.

The metal may be a combination of chromium and gold or any other suitable metal or metal combination, for example titanium or aluminium. In one embodiment the metal 7 is patterned and etched to include comer anchor pads by which the microphone may be attached to an underlying carrier.

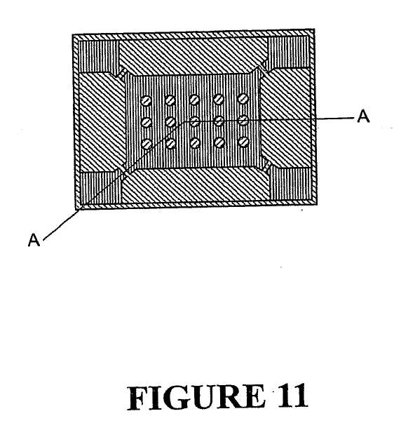

FIG. 11 shows the perforated and metallised silicon layer and the corner anchor pads. If a connection to the silicon layer 4 of the second wafer is made from the other side, all pads can be disconnected from the metal layer 7, as shown in FIG. 11. If, for example, one of the anchor pads is used as an electrode to connect to the silicon layer 4 of the second wafer, the other anchor pads may be separated from the remainder of the metal layer. Separation of the anchor pads from the bulk of the metal reduces noise contribution from the anchor pads. The separation is patterned and etched with the rest of the metal.

The acoustic holes or apertures in the silicon wafer may be circular and set within a rectangle of the silicon wafer with its centre at the centre of the silicon wafer stack but with length and breadth less than that of the wafer stack. The shape and arrangement of the apertures is chosen to provide suitable acoustic performance from the microphone.

FIG. 7A shows a representative diagrammatic side view of the silicon microphone taken through lines A-A of the plan view of FIG. 11. This shows the different layers of the silicon microphone in different regions of the microphone. As can be seen in FIG. 7A metal layer 7 does not cover the whole of the second major surface of silicon wafer 4.

As can also be seen in FIGS. 7 and 7A the cavity in the first wafer is larger than the area defined by the acoustic holes of the second wafer. By providing a bigger cavity 6 for the diaphragm 1 of the first wafer the required accuracy of the position of the acoustic holes is lessened.

As also shown in FIG. 7 during the etching of the acoustic holes a small area or gap around the perimeter of the silicon microphone may also be etched. In the preferred embodiment this etching is performed by a reactive ion etch-lag (RIE-lag). The RIE-lag is a phenomenon by which, in this case, the smaller dimensioned perimeter gap in the resist mask etches to a lesser depth than the larger dimensioned acoustic holes. Because of the RIE-lag, the gap about the perimeter of the silicon microphone does not completely etch through the silicon layer 4. This gap is shown as a step in the side views of FIGS. 7 to 10A. The incompletely etched perimeter provides lines of weakness where the bonded wafer will break when stressed, i.e. when subjected to pressure by a roller. Forming this incomplete etch allows dicing of the wafer, into individual microphone chips, without the use of abrasives or wet processes thereby reducing possible damage to the fragile diaphragm. The partial etch should be sufficiently deep to allow easy breakage of the wafer at dicing but shallow enough to allow easy handling of the wafer without breakage before dicing.

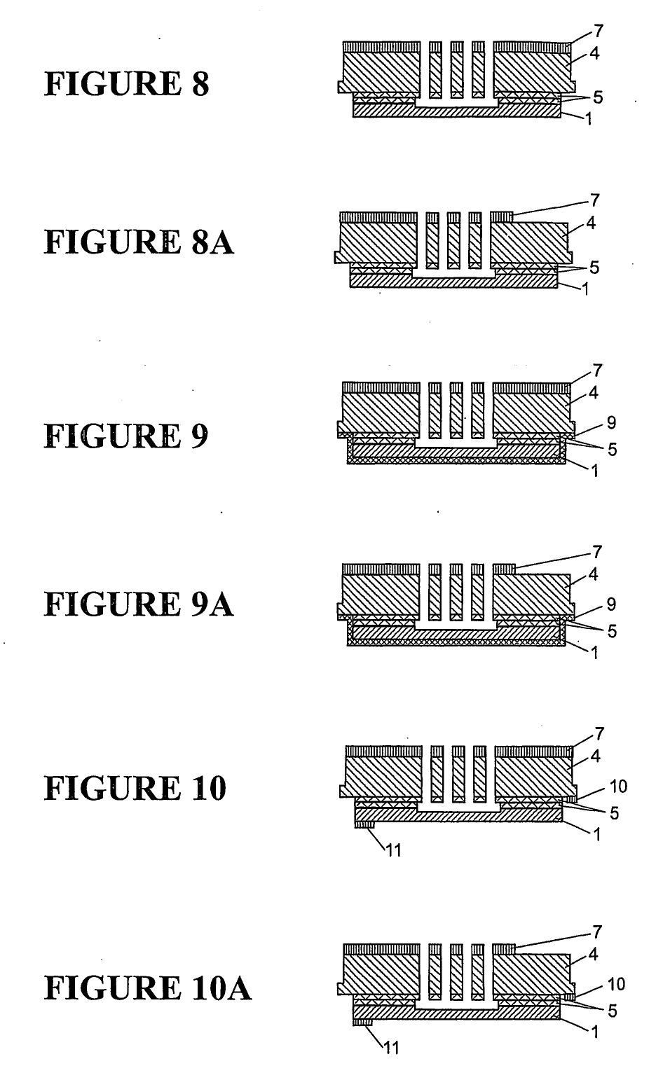

FIGS. 8 and 8A show the result of further patterning and etch steps on the bonded wafers. In these steps the oxide layer 2 is patterned to define an isolated area of the heavily doped silicon 1 which is then etched. The oxide layer 2 is then etched away from the heavily doped silicon layer 1. The oxide layers 5 around the isolated area of the diaphragm are etched away to expose portions of the generally inner major face of the second wafer 4. The oxide layer 5 inside the acoustic holes is etched away. In the case of using RIE, the opposite faces of the combined silicon wafer are etched in separate steps. After these etch steps, the remaining portion of the highly doped silicon 1, as defined by the isolated area, is less than the length of the large portion of the silicon 4 of the second wafer (excluding the partially etched silicon at the perimeter of the silicon microphone).

FIG. 9 shows one embodiment with a layer of metal formed over the heavily doped silicon layer of the first wafer and the exposed silicon of the second wafer. As shown in FIG. 9 this metal layer is sputtered globally. The metal is then etched to form at least two electrodes 10, 11 as shown in FIG. 10. At least one electrode 11 is formed on the layer of heavily doped silicon and at least one electrode 10 is formed on the exposed first, inner, major face of the silicon 4 of the second wafer.

In another embodiment the electrodes 10, 11 are formed by using a shadow mask to deposit metal directly in the required pattern.

As can be seen in FIG. 10 electrode 11 is in contact with the heavily doped layer of the first wafer 1 and electrode 10 is in contact with the silicon layer 4 of the second wafer. This allows the microphone to be connected to another device by connection bonds made from only one side of the microphone. Alternatively, as there is a layer of metal 7 on the other side of the microphone this can be. used as the electrode of the silicon 4 of the second wafer and can be connected to an underlying carrier by solder, conductive paste, or any other suitable method. By providing two electrodes for the second wafer, on opposite faces of the wafer, packaging flexibility is achieved.

Providing two electrodes on one side of the silicon microphone can also assist in probing of the silicon microphone, for example before the microphone is attached to a carrier or other system. Probing of the silicon microphone can be performed by probing needles on one side of the microphone only instead of needles on two sides of the microphone.

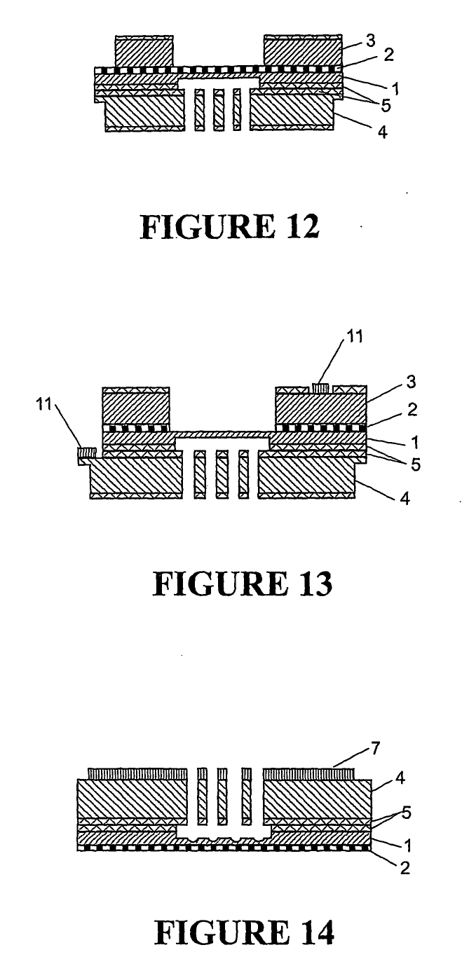

In an alternative embodiment the silicon substrate 3 is not thinned after bonding the two wafers together. In this embodiment substrate 3 is selectively thinned around the cavity and any area where an electrode will be formed. An advantage of this embodiment is that the resulting silicon microphone has improved mechanical strength. In this embodiment the sequence of etching the back plate in substrate 3 and etching the apertures in the silicon wafer is not important. FIG. 12 shows a side view of this silicon microscope after a portion of substrate 3 has been etched to form a position for an electrode. This etching may be performed at the same time that the back plate of the diaphragm is etched in substrate 3. Metal for electrodes may then be deposited on the silicon microphone using a shadow mask after removing oxide from the electrode positions. FIG. 13 shows a final view of the silicon microphone after the electrodes have been formed.

In yet another alternative embodiment substrate 3 is thinned to a predetermined thickness either before or after bonding the wafers together. Substrate 3 can then be selectively patterned and etched.

In yet another alternative embodiment one or both of the wafers may be at the final wafer thickness before processing the wafers.

FIG. 14 shows an alternative embodiment of silicon microphone of the invention. In this embodiment the diaphragm of the silicon microphone is over etched to form a series of corrugation in the diaphragm. An advantage of over etching is that it improves the strength of the silicon microphone. It should be noted that the silicon microphone of FIG. 14 is not complete and does not show any electrodes. Forming corrugations in the diaphragm can be combined with any other embodiment of silicon microphone of the invention. For example the corrugations may be combined with the microphones of FIGS. 11 or 13.

Embodiments of the invention will be further illustrated by the following examples.

### EXAMPLE

Two wafers are provided; the first wafer comprises a 4 micron layer of p⁺⁺ doped silicon, a 2 micron oxide layer, and an n-type substrate; the second wafer comprises n-type silicon.

A layer of oxide of about 1 micron is grown on each major surface of the two wafers by thermal growth. The oxide layer is then etched from a portion of the first wafer and an underlying portion of the p⁺⁺ doped silicon layer is also etched to provide a cavity in the p⁺⁺ doped silicon of about 2 microns. The etching is a dry reactive ion etch.

The cavity side of the first wafer is then fusion bonded to an oxide covered surface of the second wafer and the outer oxide layers of each wafer are stripped. The silicon substrate of the first wafer is also stripped using a suitable stripping technique for example lapping, grinding or etching.

Chromium/gold is then sputtered onto the exposed major surface of the second wafer and patterned to form the openings for acoustic holes and for areas of thinned and weakened silicon along the perimeters of the wafer. The mass of silicon in the second wafer is used to provide rigidity to the silicon microphone.

A reactive ion etch is performed to etch acoustic holes in the silicon. Reactive ion etch lag causes the etch at the perimeter of the silicon microphone wafer to etch at a slower rate and therefore a lesser depth, as the resist provides a smaller surface area for etching than that of the acoustic holes. The metal is then further etched to separate three of the corner pads from the bulk of the metal and to further define the metal area.

Following this, oxide is etched from the acoustic holes and the outer oxide layer of the first wafer is also etched away. After this step the p⁺⁺ layer of silicon and the layers of oxide between the two wafers are etched around the perimeter of the wafer to expose a portion of the front, now inner, surface of the silicon of the second wafer.

Metal is then sputtered over the p⁺⁺ layer of silicon and the exposed portions of silicon from the second wafer. The metal is patterned etched to form two electrodes.

The foregoing describes the invention including preferred forms thereof. Alterations and modifications as will be obvious to those skilled in the art are intended to be incorporated in the scope hereof as defined by the accompanying claims.

1. A method of manufacturing a silicon microphone including the steps of:
providing a first wafer including a layer of heavily doped silicon, a layer of silicon and an intermediate layer of oxide between the two silicon layers and having a first major surface on one surface of the layer of heavily doped silicon and a second major surface on the layer of silicon,
providing a second wafer of silicon having a first major surface and a second major surface,
forming a layer of oxide on at least the first major surface of the first wafer,
forming a layer of oxide on at least the first major surface of the second wafer,
etching a cavity through the oxide layer on the first major surface of the first wafer and into the layer of heavily doped silicon,
bonding the first major surface of the first wafer to the first major surface of the second wafer,
forming a metal layer on the second major surface of the second wafer,
patterning and etching acoustic holes in the metal and in the second major surface of the second wafer,
forming at least one electrode on the heavily doped silicon of the first wafer and at least one electrode on the second wafer, and
further including the step of etching the oxide layer of the first wafer from at least the back of a diaphragm during manufacturing of the silicon microphone.

2. A method of manufacturing a silicon microphone as claimed in claim 1 further including the step of thinning a portion of the second major surface of the first wafer to form a diaphragm for the silicon microphone.

3. A method of manufacturing a silicon microphone as claimed in claim 2, wherein the step of etching a portion of the second major surface of the first wafer is performed before bonding the first major surface of the first wafer to the first major surface of the second wafer.

4. A method of manufacturing a silicon microphone as claimed in claim 2, wherein the step of etching a portion of the second major surface of the first wafer is performed after bonding the first major surface of the first wafer to the first major surface of the second wafer.

5. A method of manufacturing a silicon microphone as claimed in claim 1 further including the step of etching corrugations in the diaphragm of the silicon microphone.

6. A method of manufacturing a silicon microphone as claimed in claim 1 wherein the step of forming an oxide layer on at least one major surface of both wafers includes forming an oxide layer on both major surfaces of both wafers.

7. A method of manufacturing a silicon microphone as claimed in claim 1 wherein the oxide layers formed on the major faces of the wafers are grown on the major surfaces of the wafers.

8. A method of manufacturing a silicon microphone as claimed in claim 1 wherein any other suitable method is used to form the oxide layers.

9. A method of manufacturing a silicon microphone as claimed in claim 2 wherein the oxide layer formed on the second major surface of the second wafer is removed before the first wafer is thinned.

10. A method of manufacturing a silicon microphone as claimed in claim 3 wherein the oxide layer formed on the second major surface of the first wafer is removed before the first wafer is thinned.

11. A method of manufacturing a silicon microphone as claimed in claim 1 wherein the step of forming a layer of metal on the second major surface of the second wafer is performed by sputtering metal onto the second major surface of the second wafer.

12. A method of manufacturing a silicon microphone as claimed in claim 1 further including the step of etching a portion of the second wafer from its second major surface to close to its first major surface, the portion being about the perimeter of the wafer.

13. A method of manufacturing a silicon microphone as claimed in claim 12 wherein the etching of the perimeter portion of the second wafer is performed when the acoustic holes are etched.

14. A method of manufacturing a silicon microphone as claimed in claim 1 wherein when the first wafer is thinned at its second major surface, the first wafer is thinned to the intermediate oxide layer.

15. A method of manufacturing a silicon microphone as claimed in claim 1 wherein the step of forming electrodes on the heavily doped silicon layer of the first wafer and on the second wafer is performed by forming a metal electrode layer over the entire exposed surface of the heavily doped silicon layer of the first wafer and the exposed surface of the first major surface of the second wafer.

16. A method of manufacturing a silicon microphone as claimed in claim 15 wherein the metal electrode layer is etched to form the electrodes.

17. A method of manufacturing a silicon microphone as claimed in claim 1 wherein the step of forming electrodes on the heavily doped silicon layer of the first wafer and on the second wafer is performed by sputtering metal and using a shadow mask to pattern the electrodes.

18. A method of manufacturing a silicon microphone as claimed in claim 1 wherein the layer of metal formed on the second major surface of the second wafer is an alloy or mixture of chromium and gold.

19. A method of manufacturing a silicon microphone as claimed in claim 1 wherein any suitable conductive metal is used for the electrode.

20. A method of manufacturing a silicon microphone as claimed in claim 1 wherein when the acoustic holes are patterned and etched into the metal layer formed on the second major surface of the second wafer, anchors are patterned and formed at the edges of the wafer in the metal layer formed on the second major surface of the second wafer.

21. A method of manufacturing a silicon microphone as claimed in claim 20 wherein one of the anchors may be used as an electrode.

22. A method of manufacturing a silicon microphone as claimed in claim 21, wherein the other anchors include both a portion of the second wafer and a cover portion of metal.

23. A method of manufacturing a silicon microphone as claimed in claim 22 wherein the cover metal portions are separated from metal surrounding the acoustic holes.

24. A method of manufacturing a silicon microphone as claimed in claim 23 wherein the separation step is performed by patterning and etching the separation when the acoustic holes are patterned and etched in the metal.

25. A silicon microphone formed in accordance with the method of claim 1.
